(19) United States
(12) Patent Application Publication
(10) Pub. No.: US 2026/0139718 A1
(43) Pub. Date: May 21, 2026

(54) DAMPING STRUCTURE, ELECTRONIC DEVICE AND DAMPING ASSEMBLY

(71) Applicants: INVENTEC (PUDONG) TECHNOLOGY CORPORATION, Shanghai (CN); INVENTEC CORPORATION, Taipei City (TW)

(72) Inventors: Hsin-Haou HUANG, Taipei City (TW); Pin-Chieh CHEN, Taipei City (TW); Po-Hsiu CHEN, Taipei City (TW); Hsieh-Liang TSAI, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/226,731

(22) Filed: Jun. 3, 2025

(30) Foreign Application Priority Data
Nov. 20, 2024 (CN) 202411669306.6
Nov. 21, 2024 (CN) 202411681027.1
Nov. 21, 2024 (CN) 202411681732.1

(51) Int. Cl. F16F 7/104; G11B 33/08; H05K 7/14

(52) U.S. Cl. CPC F16F 7/104; G11B 33/08; F16F 2238/022; F16F 2238/026; H05K 7/1488

(57) ABSTRACT

A damping structure includes a first damping assembly and a second damping assembly. The first damping assembly includes an elastic member and a first mass block. The elastic member includes two assembling portions and a curved portion. The assembling portions are configured to be assembled on a chassis. Opposite ends of the curved portion are connected to the assembling portions. A distance between a central part of the curved portion and the chassis is longer than a distance between the opposite ends of the curved portion and the chassis. The first mass block is disposed on the central part of the curved portion. The second damping assembly includes a compression spring and a second mass block. An end of the second mass block is connected to an end of the compression spring. Another end of the compression spring is disposed on one of the assembling portions.

### CROSS-REFERENCE TO RELATED APPLICATIONS

This non-provisional application claims priority under 35 U.S.C. § 119(a) on Patent Application No(s). 202411669306.6 filed in China, on Nov. 20, 2024, Patent Application No(s). 202411681732.1 filed in China, on Nov. 21, 2024, and Patent Application No(s). 202411681027.1 filed in China, on Nov. 21, 2024, the entire contents of which are hereby incorporated by reference.

### BACKGROUND OF THE INVENTION

### Technical Field of the Invention

The invention relates to a damping structure, an electronic device and a damping assembly, more particularly to a damping structure, an electronic device and a damping assembly having a mass block.

### Description of the Related Art

With the rapid development of technology, the computation performance of processors of an electronic product is improved significantly, while a large amount of heat is generated thereby at the same time. In order to prevent the damage to the processors caused by such heat, a fan is generally provided in the electronic product to cool the processors, so that the processors can operate within an adequate temperature range.

The fan operating in a high speed may generate vibration. When such vibration is transferred to a hard disk drive disposed in the electronic product, a position error signals (PES) may be caused in the operating hard disk drive, thereby adversely affecting an accuracy of data reading and causing a poor read speed of the hard disk drive, for example, causing a low input/output per second (IOPS). Accordingly, an overall performance of the electronic product may be degraded, and data loss may even be caused. Thus, a vibration suppression is critical in the field of the electronic product. Generally, manufactures may additionally assemble a damping member in a chassis of the electronic product to absorb the vibration generated by the fan. However, the conventional damping member is expensive. In addition, it is hard to assemble the damping member in the chassis due to excessive components of the damping member and limited inner space of the chassis. Moreover, the conventional damping member cannot be compatible with different specifications of the chassis. That is, the manufactures need to adopt different sizes of the damping member for different specifications of the chassis, thereby increasing an assembly cost of the damping member. Therefore, lowering the assembly cost while maintaining the damping effect of the damping member is one of the key issues that researchers need to address.

### SUMMARY OF THE INVENTION

The invention provides a damping structure, an electronic device and a damping assembly in order to lower the assembly cost while maintaining the damping effect of the damping structure.

One embodiment of the invention provides a damping structure configured to be disposed in a chassis. The damping structure includes a first damping assembly and at least one second damping assembly. The first damping assembly includes an elastic member and a first mass block. The elastic member includes two assembling portions and a curved portion. The two assembling portions are configured to be assembled on the chassis. Two opposite ends of the curved portion are connected to the two assembling portions, respectively. A distance between a central part of the curved portion and the chassis is longer than a distance between the two opposite ends of the curved portion and the chassis. The first mass block is disposed on the central part of the curved portion. The at least one second damping assembly includes a compression spring and a second mass block. An end of the second mass block is connected to an end of the compression spring. Another end of the compression spring of the at least one second damping assembly is disposed on one of the two assembling portions of the first damping assembly.

Another embodiment of the invention provides an electronic device including a chassis, a hard disk drive, at least one fan and at least one damping structure. The hard disk drive is disposed in the chassis. The at least one fan is disposed in the chassis. The at least one damping structure is located between the hard disk drive and the at least one fan, and includes a first damping assembly and at least one second damping assembly. The first damping assembly includes an elastic member and a first mass block. The elastic member includes two assembling portions and a curved portion. The two assembling portions are configured to be assembled on the chassis. Two opposite ends of the curved portion are connected to the two assembling portions, respectively. A distance between a central part of the curved portion and the chassis is longer than a distance between the two opposite ends of the curved portion and the chassis. The first mass block is disposed on the central part of the curved portion. The at least one second damping assembly includes a compression spring and a second mass block. An end of the second mass block is connected to an end of the compression spring. Another end of the compression spring of the at least one second damping assembly is disposed on one of the two assembling portions of the first damping assembly.

Another embodiment of the invention provides a damping assembly configured to be disposed in a chassis. The damping assembly includes an elastic member and a mass block. The elastic member includes two assembling portions and a curved portion. The two assembling portions are configured to be assembled on the chassis. Two opposite ends of the curved portion are connected to the two assembling portions, respectively. A distance between a central part of the curved portion and the chassis is longer than a distance between the two opposite ends of the curved portion and the chassis. The mass block is disposed on the central part of the curved portion.

Another embodiment of the invention provides a damping assembly configured to be disposed in a chassis. The damping assembly includes a compression spring and a mass block. An end of the compression spring is configured to be disposed on the chassis. An end of the mass block is connected to another end of the compression spring.

According to the damping structure, the electronic device and the damping assembly disclosed in the above embodiment, the distance between the central part of the curved portion and the chassis is longer than the distance between the two opposite ends of the curved portion and the chassis. That is, the curved portion is single wave-shaped. The opposite end of the two compression springs of the two second damping assemblies are connected to the ends of the two second mass block and the two assembling portions of the first damping assembly, respectively. The natural frequency of the damping structures is adjustable. Therefore, the vibrations can be damped by the damping structures of the electronic device effectively under different operating conditions. When one of the natural frequencies of the damping structures matches the vibration frequency of the at least one fan, a resonance will be generated, and the strong amplitude enhancement effect may be generated by the damping structures. The interaction between the vibrations generated by the at least one fan during operation and the elastic member and the two compression springs of the damping structures can be conducted along the path in which the vibrations are transferred. Specifically, the vibrations generated by the at least one fan during operation may be transferred to the damping structures. The wave-shaped curved portion of the elastic member and the two compression springs can absorb the vibrations effectively, and convert the vibrations into kinetic energy of the elastic member and the two compression springs. Accordingly, the vibrations generated by the at least one fan during operation can be confined within the damping structures to dissipate energy. In addition, the damping structures can be facilitated to be assembled in the limited space between the hard disk drive and the at least one fan and be prevented from interfering with other obstructions disposed in the aforementioned space. Thus, the damping structures can be adaptable to different specifications of the chassis. Accordingly, the assembly cost of the damping structures can be lowered while maintaining the damping effect of the damping structures.

In addition, compared to conventional damping structure including a single elastic member and a single mass block merely, the damping structure of the invention includes a composite including the elastic member, the first mass block, the compression spring and the second mass block. Therefore, a damping frequency bandwidth of the damping structure can be widened.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a plane view of an electronic device in accordance with a first embodiment of the invention;

FIG. 2 is a partially enlarged perspective view of the electronic device in FIG. 1;

FIG. 3 is a plane view of the electronic device in FIG. 2;

FIG. 4 is an exploded view of the electronic device in FIG. 2;

FIG. 5 is a top view of an elastic member of the electronic device in FIG. 1;

FIG. 6 is a side view of the elastic member of the electronic device in FIG. 1;

FIG. 7 is a plane view of an electronic device in accordance with a second embodiment of the invention;

FIG. 8 is a partially enlarged perspective view of the electronic device in FIG. 7;

FIG. 9 is a plane view of an electronic device in accordance with a third embodiment of the invention; and

FIG. 10 is perspective a view of a second damping assembly of the electronic device in FIG. 9.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

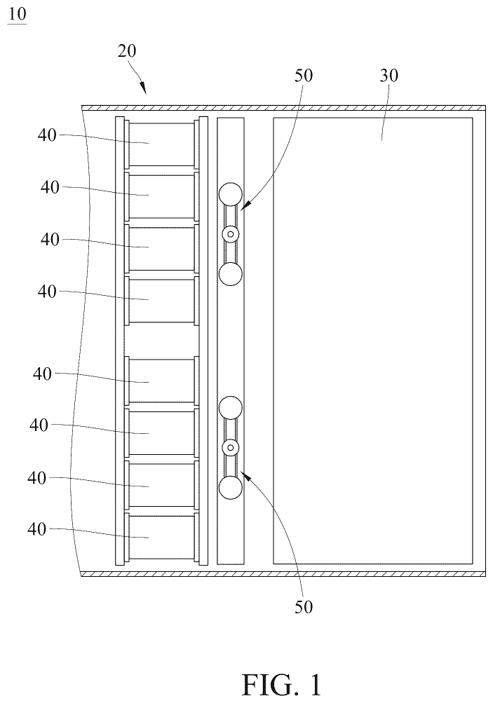

Please refer to FIG. 1, which is a plane view of an electronic device 10 in accordance with a first embodiment of the invention. In this embodiment, the electronic device 10 includes a chassis 20, a hard disk drive 30, a plurality of fans 40 and a plurality of damping structures 50. The hard disk drive 30 and the fans 40 are disposed in the chassis 20. The damping structures 50 are disposed between the hard disk drive 30 and the fans 40 as local resonators, such that an interaction between vibrations generated by the fans 40 during operation and the damping structures 50 can be conducted along a path where the vibrations are transferred. Therefore, the vibrations generated by the fans 40 during operation and transferred to the hard disk drive 30 can be damped. Accordingly, the read speed of the hard disk drive 30, such as input/output per second (IOPS) of the hard disk drive 30, is prevented from being reduced by the vibrations.

When a frequency of external vibrations is nearly equal to a resonant frequency of the damping structures 50, a local resonance of the local resonators can be induced to form a vibration bandgap. The local resonance is caused by the interaction between a mass component and elastic waves generated by elastic members of the local resonators, thereby enhancing the vibration suppression effect. In addition, the vibrations of a frequency ranging from, for example, 300 hertz (Hz) to 400 Hz and 1200 Hz to 1500 Hz can be absorbed by the damping structures 50. Moreover, a fundamental frequency and overtones thereof around 300 Hz to 400 Hz are, for example, a fundamental frequency of the vibrations generated by the fans 40 during operation, and a frequency ranging from 1200 Hz to 1500 Hz is, for example, a sensitive frequency in which the hard disk drive 30 is susceptible to the vibrations.

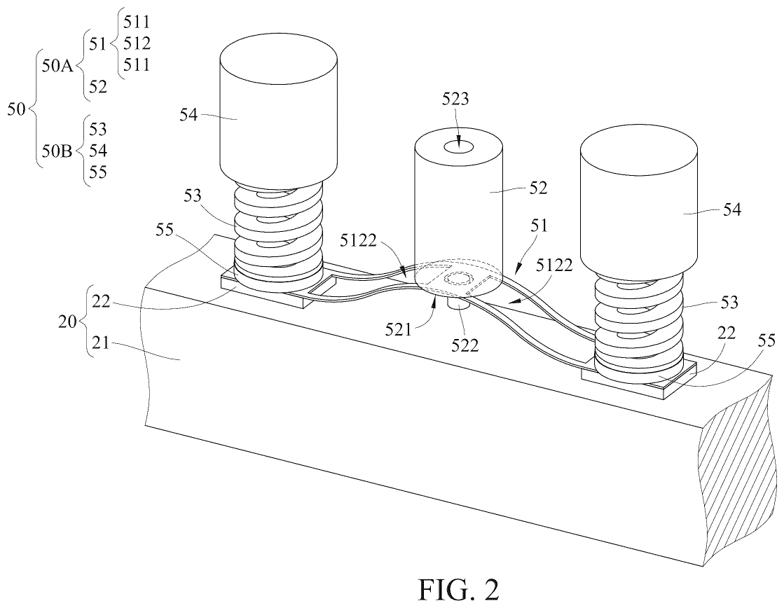

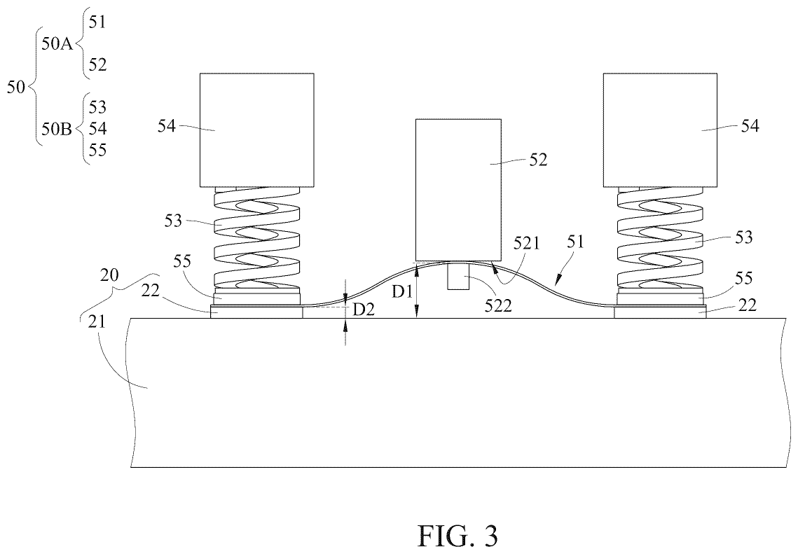

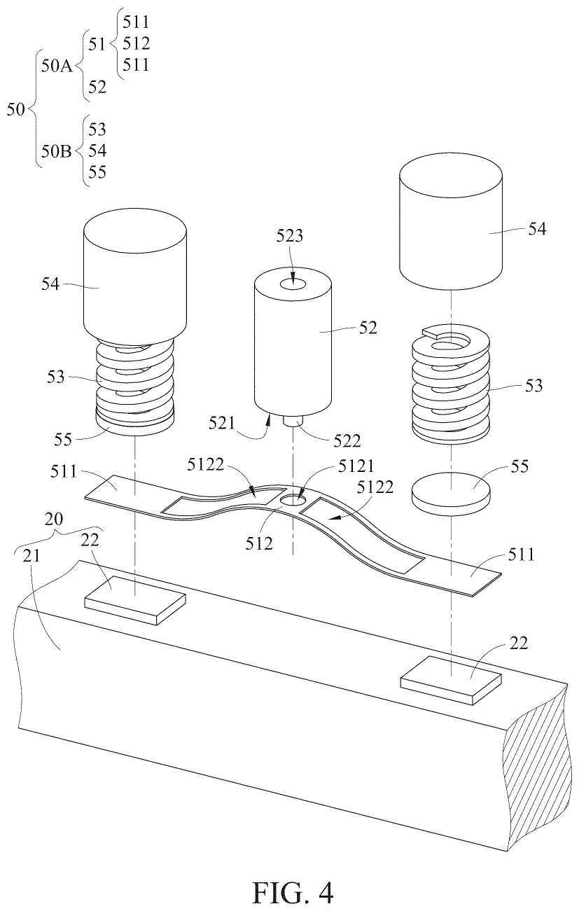

Please refer to FIG. 1 to FIG. 4, where FIG. 2 is a partially enlarged perspective view of the electronic device 10 in FIG. 1, FIG. 3 is a plane view of the electronic device 10 in FIG. 2, and FIG. 4 is an exploded view of the electronic device 10 in FIG. 2.

Each of the damping structures 50 includes a first damping assembly 50A and at least one second damping assembly 50B. The first damping assembly 50A includes an elastic member 51 and a first mass block 52. The at least one second damping assembly 50B includes a compression spring 53 and a second mass block 54. That is, the elastic member 51, the first mass block 52, the compression spring 53 and the second mass block 54 together form a resonator, and a natural frequency of the resonator follows the equation:

$$f = \frac{1}{2 π} \sqrt{\frac{k}{m}} ,$$

where the symbol “f” in the aforementioned equation refers to the natural frequency (unit: hertz, Hz) of the resonator, the symbol “k” in the aforementioned equation refers to a stiffness (unit: newtons per meter, N/m) of the elastic member 51 and the compression spring 53, and the symbol “m” in the aforementioned equation refers to a mass (unit: kilograms, kg) of the first mass block 52 and the second mass block 54. Furthermore, the less the stiffness of the elastic member 51 and the compression spring 53 is, the lower the natural frequency of the resonator is. In addition, the greater the mass of the first mass block 52 and the second mass block 54 is, the lower the natural frequency of the resonator is.

In the first damping assembly 50A, the elastic member 51 includes two assembling portions 511 and a curved portion 512. The two assembling portions 511 are assembled on the chassis 20. In detail, the chassis 20 includes a body portion 21 and a plurality of first magnetic members 22. The first magnetic members 22 are, for example, magnets, but the invention is not limited thereto. In other embodiments, the first magnetic members may be any objects that can be attracted by a magnet. The first magnetic members 22 are disposed on the body portion 21. The elastic member 51 is made of, for example, magnetic material. The first magnetic members 22 attract the two assembling portions 511 of the elastic member 51 to install the elastic member 51 onto the chassis 20 firmly. Accordingly, the vibrations generated by the fans 40 during operation can be effectively transferred to the damping structures 50.

Two opposite ends of the curved portion 512 are connected to the two assembling portions 511, respectively. A distance D1 between a central part of the curved portion 512 and the body portion 21 of the chassis 20 is longer than a distance D2 between the two opposite ends of the curved portion 512 and the body portion 21 of the chassis 20. That is, the curved portion 512 is, for example, single wave-shaped, such that the elastic member 51 can absorb the vibration effectively. The elastic member 51 converts the vibration into kinetic energy of the elastic member 51.

The first mass block 52 is disposed on the central part of the curved portion 512. That is, the first mass block 52 is disposed at a wave crest of the curved portion 512. In detail, the central part of the curved portion 512 has an assembling hole 5121. The first mass block 52 has a curved portion 512 and an assembling protrusion 522. The surface 521 is, for example, flat, and faces the curved portion 512. The assembling protrusion 522 protrudes from the surface 521. The assembling protrusion 522 is assembled into the assembling hole 5121. Specifically, the assembling protrusion 522 is, for example, screwed into the assembling hole 5121. In addition, when the clastic member 51 is thin enough for the assembling protrusion 522 to be disposed therethrough, a nut (not shown) can additionally be fastened to the portion of the assembling protrusion 522 which passes through the elastic member 51. That is, the nut can be fastened on a side of the elastic member 51 away from the first mass block 52 to fix the first mass block 52. Moreover, when the first mass block 52 is light, a mass of the nut can be taken into account along with a mass of the first mass block 52 to adjust the natural frequency of the damping structures 50. Furthermore, according to an application and required physical properties, the first mass block 52 may be made of, for example, a metal or a rubber material with damping characteristics.

In this embodiment, the at least one second damping assembly 50B includes, for example, two second damping assemblies 50B, and the two second damping assemblies 50B are disposed on the two assembling portions 511 of the first damping assembly 50A, respectively. In detail, ends of the two compression springs 53 of the two second damping assemblies 50B are connected to the two assembling portions 511 of the first damping assembly 50A, respectively. The two compression springs 53 are made of, for example, metal, acrylic, resin or plastic material. Ends of the two second mass blocks 54 are connected to another ends of the two compression springs 53, respectively. According to an application and required physical properties, the two second mass blocks 54 may be made of, for example, a metal or a rubber material with damping characteristics. The specific embodiments of the invention are merely exemplary, and do not limit the scope of the invention. In fact, the damping effect can also be realized by providing one second damping assembly 50B. Any modifications or variations made within the spirit and scope of the invention, including variations in quantity, are intended to be included within the scope of protection of the invention.

When the vibrations generated by the fans 40 during operation are transferred to the damping structures 50, if the natural frequency of the damping structures 50 matches the vibration frequency of the fans 40, a strong amplitude enhancement effect may be generated by the damping structures 50. Accordingly, the vibrations generated by the fans 40 can be absorbed via a resonance generated by an oscillation along a direction perpendicular to a normal direction of a top surface of the body portion 21 (i.e. along a vertical direction) produced by the first mass block 52 of the first damping assembly 50A on the elastic member 51 and an oscillation along the aforementioned direction produced by the two second mass blocks 54 of the two second damping assemblies 50B on the two compression springs 53. Then, the vibrations generated by the fans 40 can be effectively transferred to the damping structures 50 via the resonance. The first mass block 52 and the two second mass blocks 54 with the mass corresponding to the actual vibration may be adopted.

In this embodiment, the curved portion 512 may have two notches 5122. The two notches 5122 are located on two opposite sides of the assembling hole 5121, respectively. A flexibility of the curved portion 512 can be increased via the two notches 5122, thereby improving a damping capacity of the first damping assembly 50A. In detail, a Young's modulus of the clastic member 51 can be adjusted via the two notches 5122. The so-called “Young's modulus” can affect the stiffness and an elastic deformation capacity of the elastic member 51, thereby affecting the natural frequency of the first damping assembly 50A. The less the Young's modulus is, the lower the natural frequency is.

Furthermore, when the vibrations generated by the fans 40 during operation are transferred to the damping structures 50, if the natural frequency of the damping structures 50 matches the vibration frequency of the fans 40, the strong amplitude enhancement effect may be generated by the damping structures 50. The natural frequency of the damping structures 50 may be adjusted (e.g., lowered), for example, by lowering the stiffness of the elastic member 51 via a reduction of a thickness of the elastic member 51 of the first damping assembly 50A. Alternatively, the natural frequency of the damping structures 50 may be adjusted (e.g., lowered), for example, by lowering the stiffness of the elastic member 51 via an increase a size of the two notches 5122.

In this embodiment, each of the damping structures 50 may include two second magnetic members 55. The two second magnetic members 55 are, for example, magnets, but the invention is not limited thereto. In other embodiments, the second magnetic members may be any objects that can be attracted by a magnet. The two second magnetic members 55 are connected to ends of the two compression springs 53 of the second damping assembly 50B away from the two second mass blocks 54, respectively. The two compression springs 53 are fixed to the elastic member 51 of the first damping assembly 50A via the two second magnetic members 55 attracting the clastic member 51.

In this embodiment, the distance D1 between the central part of the curved portion 512 and the body portion 21 of the chassis 20 is longer than the distance D2 between the two opposite ends of the curved portion 512 and the body portion 21 of the chassis 20. That is, the curved portion 512 is single wave-shaped. The opposite end of the two compression springs 53 of the two second damping assemblies 50B are connected to the ends of the two second mass blocks 54 and the two assembling portions 511 of the first damping assembly 50A, respectively. The natural frequency of the damping structures 50 may be adjusted by the mass of 52 and 54 or radius of curvature of 51, which will be described in detail later. Therefore, the vibrations can be damped by the damping structures 50 of the electronic device 10 effectively under different operating conditions. When one of the natural frequencies of the damping structures 50 matches the vibration frequency of the fans 40, a resonance will be generated, and the strong amplitude enhancement effect may be generated by the damping structures 50. The interaction between the vibrations generated by the fans 40 during operation and the elastic member 51 and the two compression springs 53 of the damping structures 50 can be conducted along the path in which the vibrations are transferred. Specifically, the vibrations generated by the fans 40 during operation may be transferred to the damping structures 50. The wave-shaped curved portion 512 of the elastic member 51 and the two compression springs 53 can absorb the vibrations effectively, and convert the vibrations into kinetic energy of the elastic member 51 and the two compression springs 53. Accordingly, the vibrations generated by the fans 40 during operation can be confined within the damping structures 50 to dissipate energy. In addition, the damping structures 50 can be facilitated to be assembled in the limited space between the hard disk drive 30 and the fans 40 and be prevented from interfering with other obstructions disposed in the aforementioned space. Thus, the damping structures 50 can be adaptable to different specifications of the chassis 20. Accordingly, the assembly cost of the damping structures 50 can be lowered while maintaining the damping effect of the damping structures 50.

Moreover, the electronic device 10 includes multiple first magnetic members 22 and the multiple second magnetic members 55. The first magnetic members 22 attract the two assembling portions 511 of the first damping assembly 50A to install the elastic member 51 onto the chassis 20. The two compression springs 53 of the two second damping assemblies 50B are fixed to the elastic member 51 via the two second magnetic members 55 attracting the elastic member 51. Therefore, the damping structures 50 can be easily assembled and disassembled according to a damping requirement via the first magnetic members 22 and the two second magnetic members 55 without fastening the elastic member 51 to the chassis 20 via additional fasteners and fastening the two compression springs 53 to the two assembling portions 511 via additional fasteners. Accordingly, the flexibility of assembling the damping structures 50 can be further improved. In addition, the two assembling portions 511 of the elastic member 51 can be more firmly fixed to the chassis 20 via the first magnetic members 22. Therefore, the damping structures 50 can be firmly fixed to the chassis 20 without being detached from the chassis 20 during oscillation caused by insufficient stiffness of a boundary of the elastic member 51. Accordingly, the ineffective transfer of the vibration to the damping structures 50 is prevented from disturbing the generation of the resonance.

In this embodiment, a side of the first mass block 52 away from assembling protrusion 522 has an assembling recess 523. The assembling recess 523 is, for example, a threaded structure (not shown), and is configured for additional mass blocks to be assembled therein to adjust the overall mass of the first damping assembly 50A.

In this embodiment, there are multiple fans 40 and multiple damping structures 50, but the invention is not limited thereto. In other embodiments, there may be one fan and one damping structure merely.

In this embodiment, the chassis 20 includes multiple first magnetic members 22, and the multiple first magnetic members 22 attract the two assembling portions 511 of the first damping assembly 50A of the damping structures 50 to install the elastic member 51 onto the chassis 20 firmly, but the invention is not limited thereto. In other embodiments, the chassis may not include the first magnetic member, and the two assembling portions of the damping structures are, for example, screwed to the chassis via screws.

In this embodiment, the central part of the curved portion 512 of the first damping assembly 50A has the assembling hole 5121, and the first mass block 52 has the assembling protrusion 522, but the invention is not limited thereto. In other embodiments, the central part of the curved portion may have the assembling protrusion, and the first mass block may have the assembling hole.

In this embodiment, the two compression springs 53 of the two second damping assemblies 50B are fixed to the elastic member 51 of the first damping assembly 50A via the two second magnetic members 55 attracting the elastic member 51, but the invention is not limited thereto. In other embodiments, the two compression springs may be fixed to the elastic member via other fixing members.

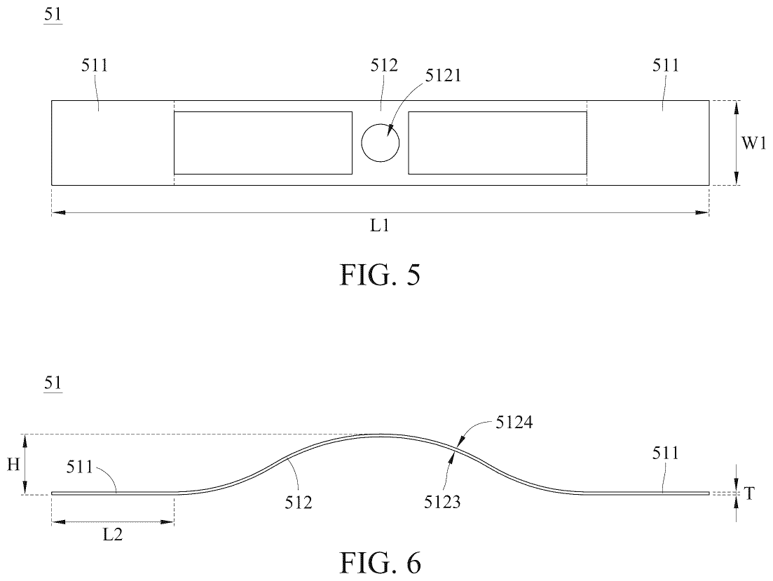

Please refer to FIG. 5 and FIG. 6, where FIG. 5 is a top view of an elastic member 51 of the electronic device 10 in FIG. 1, and FIG. 6 is a side view of the elastic member 51 of the electronic device 10 in FIG. 1.

In this embodiment, when the natural frequency of the damping structures 50 is greater than or equal to 300 Hz and less than or equal to 400 Hz, a ratio of a length L1 of the elastic member 51 to the width W1 of the elastic member 51 may be greater than or equal to 7 and less than or equal to 8. For example, a ratio of the length L1 of the elastic member 51 and the width W1 of the elastic member 51 may be 7.75:1. Alternatively, a ratio of the length L1 of the elastic member 51, the width W1 of the elastic member 51 and a height H of the elastic member 51 may be 11:1.5:1. In the preferred embodiment, the length L1 of the elastic member 51 is, for example, greater than or equal to 69 millimeters and less than or equal to 70 millimeters. The thickness T of the elastic member 51 is, for example, greater than or equal to 0.3 millimeters.

The greater thickness T the elastic member 51 is, the greater stiffness the elastic member 51 is. For example, when the thickness T of the elastic member 51 is 0.3 millimeters, the stiffness of the elastic member 51 is 57058 N/m. When the thickness T of the elastic member 51 is 0.5 millimeters, the stiffness of the elastic member 51 is 223623 N/m. When the thickness T of the elastic member 51 is 0.8 millimeters, the stiffness of the elastic member 51 is 709801 N/m. When the thickness T of the elastic member 51 is 1 millimeter, the stiffness of the elastic member 51 is 1148771 N/m.

In this embodiment, under a condition where the natural frequency of the damping structures 50 is ranging from 300 Hz to 400 Hz, a length L2 of each of the two assembling portions 511 is, for example, greater than or equal to 12 millimeters and less than or equal to 14 millimeters. In addition, the curved portion 512 has a curved bottom surface 5123 and a curved top surface 5124 facing away from each other. The curved bottom surface 5123 faces the body portion 21 of the chassis 20. For example, a radius of curvature of the curved bottom surface 5123 is larger than or equal to 21 millimeters and less than or equal to 22 millimeters, and a radius of curvature of the curved top surface 5124 is larger than or equal to 20 millimeters and less than or equal to 21 millimeters. In detail, the radius of curvature of the curved bottom surface 5123 may be 21.98 millimeters, and the radius of curvature of the curved top surface 5124 may be 20.23 millimeters, but the invention is not limited thereto. Specifically, a radius of curvature of the curved portion 512 can be adjusted via a counterweight of the first mass block 52, thereby correspondingly changing the natural frequency and an oscillation mode of the damping structures 50. Generally, the greater the radius of curvature of the curved portion 512 is, the lower the stiffness of the elastic member 51 is, and the natural frequency of the resonator can be lowered by lowering the stiffness of the elastic member 51.

In the preferred embodiment, for example, the counterweight of the first mass block 52 may be 29 grams. The two second mass blocks 54 connected to the two opposite ends of the elastic member 51 may be 35 grams. A stiffness of the two compression spring 53 may be 140 N/m. The stiffness of a portion of the elastic member 51 located between the first mass block 52 and one of the two second mass blocks 54 may be adjusted to be 170 N/m. Under the aforementioned condition, the natural frequency of the damping structures 50 can be correspondingly adjusted to be 350 Hz, but the invention is not limited thereto. In other embodiments, the natural frequency of the damping structures 50 may be correspondingly adjusted to be, for example, less than 350 Hz by increasing a counterweight of the two second mass blocks 54. Alternatively, the natural frequency of the damping structures 50 may be correspondingly adjusted to be, for example, greater than 350 Hz by reducing the radius of curvature of the portion of the curved portion 512 located between the first mass block 52 and one of the two second mass blocks 54.

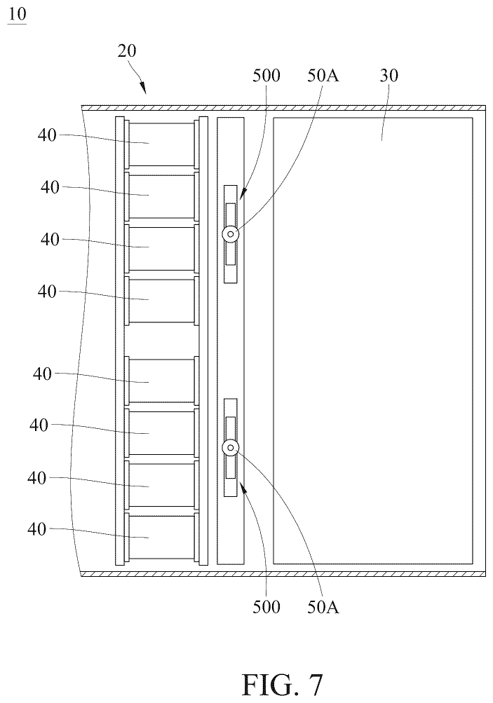

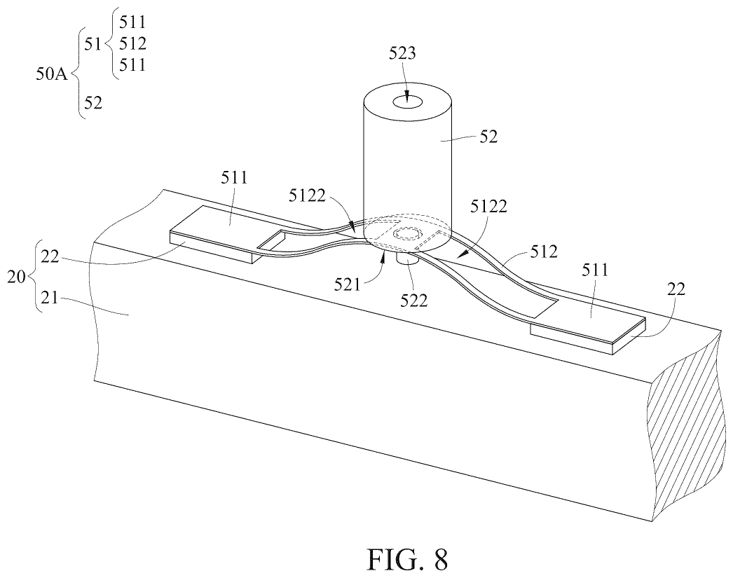

Please refer to FIG. 7 and FIG. 8, where FIG. 7 is a plane view of an electronic device 10 in accordance with a second embodiment of the invention, and FIG. 8 is a partially enlarged perspective view of the electronic device 10 in FIG. 7. In this embodiment, there are multiple damping structures 500. Each damping structure 500 includes one first damping assemblies 50A and does not include the second damping assembly 50B in FIG. 2. Each of first damping assemblies 50A may be independently disposed between a hard disk drive 30 and fans 40 as local resonators, such that an interaction between vibrations generated by the fans 40 during operation and the first damping assemblies 50A can be conducted along a path in which the vibrations are transferred. Therefore, the vibrations generated by the fans 40 during operation can be damped. For better understanding and case of description, the components identical to those in the first embodiment are designated with the same reference numerals.

Each of the first damping assemblies 50A includes an elastic member 51 and a first mass block 52. That is, the clastic member 51 and the first mass block 52 together form a resonator. In this embodiment, a distance D1 between a central part of a curved portion 512 of the elastic member 51 and the body portion 21 of a chassis 20 of the electronic device 10 is longer than a distance D2 between the two opposite ends of the curved portion 512 and the body portion 21 of the chassis 20. That is, the curved portion 512 is, for example, single wave-shaped. In addition, a mass of the first mass block 52 can be adjusted to correspondingly adjust a natural frequency of the first damping assemblies 50A. Therefore, the vibrations can be damped by the first damping assemblies 50A of the electronic device 10 effectively under different operating conditions. Specifically, the vibrations generated by the fans 40 during operation may be transferred to the first damping assemblies 50A. The wave-shaped curved portion 512 can absorb the vibrations effectively, and convert the vibrations into kinetic energy of the elastic member 51. Accordingly, the vibrations generated by the fans 40 during operation can be confined within the first damping assemblies 50A, thereby dissipating, for example, 12% of a vibrating energy.

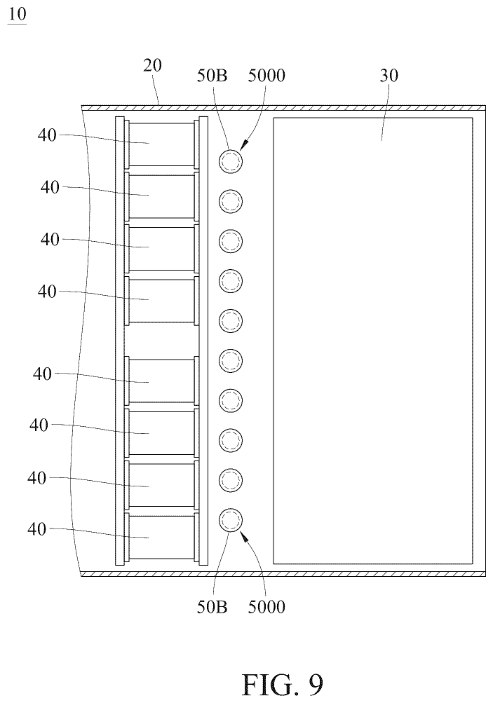

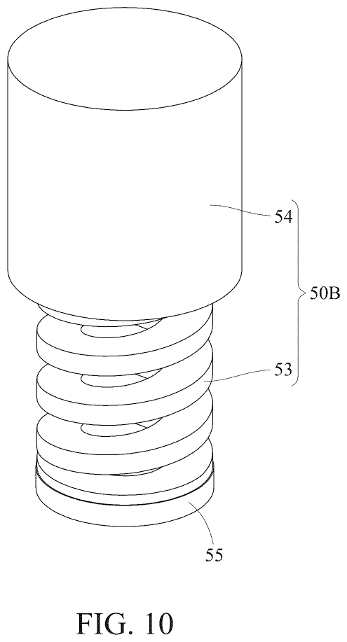

Please refer to FIG. 9 and FIG. 10, where FIG. 9 is a plane view of an electronic device 10 in accordance with a third embodiment of the invention, and FIG. 10 is perspective a view of a second damping assembly 50B (may be simply referred as a damping assembly) of the electronic device 10 in FIG. 9. In this embodiment, there are multiple damping structures 5000. Each damping structure 5000 includes one second damping assembly 50B and does not include the first damping assemblies 50A in FIG. 2. Each of the second damping assemblies 50B may be independently disposed between the hard disk drive 30 and the fans 40 as local resonators, such that an interaction between vibrations generated by the fans 40 during operation and the second damping assemblies 50B can be conducted along a path in which the vibrations are transferred. Therefore, the vibrations generated by the fans 40 during operation can be damped. For better understanding and case of description, the components identical to those in the first embodiment are designated with the same reference numerals.

Each of the second damping assemblies 50B includes a compression spring 53 and a second mass block 54. That is, the compression spring 53 and the second mass block 54 together form a resonator. When the vibrations generated by the fans 40 during operation are transferred to the second damping assemblies 50B, if a natural frequency of the second damping assemblies 50B matches the vibration frequency of the fans 40, a strong amplitude enhancement effect may be generated by the second damping assemblies 50B. Accordingly, the vibrations generated by the fans 40 can be absorbed via a resonance generated by an oscillation along a direction perpendicular to a normal direction of a top surface of a chassis 20 (i.e. along a vertical direction) caused by the second mass block 54 on the compression spring 53. Then, the vibrations generated by the fans 40 can be effectively transferred to the second damping assemblies 50B via the resonance. The second mass block 54 with the mass corresponding to the actual vibration may be adopted. For example, the second mass block 54 having a mass of 28 grams may be adopted, and fifteen second damping assemblies 50B may be spaced apart within the chassis 20. The second damping assembly 50B can effectively absorb the vibrations of a target frequency ranging from 300 Hz to 400 Hz generated by the fans 40 via the natural frequencies of the second damping assembly 50B. Alternatively, the second mass block 54 having a mass of 38 grams may be adopted, and fourteen second damping assemblies 50B may be spaced apart within the chassis 20. The second damping assembly 50B can effectively absorb the vibrations of a target frequency ranging from 300 Hz to 350 Hz generated by the fans 40 via the natural frequencies of the second damping assembly 50B.

In this embodiment, an end of the second mass block 54 of each of the second damping assemblies 50B is connected to an end of the compression spring 53. In addition, a mass of the second mass block 54 can be adjusted to correspondingly adjust the natural frequency of the second damping assemblies 50B. Therefore, the vibrations can be damped by the second damping assemblies 50B of the electronic device 10 effectively under different operating conditions. Specifically, the vibrations generated by the fans 40 during operation may be transferred to the second damping assemblies 50B. The compression spring 53 can absorb the vibrations effectively, and convert the vibrations into kinetic energy of the compression spring 53. Accordingly, the vibrations generated by the fans 40 during operation can be confined within the second damping assemblies 50B, thereby dissipating, for example, 65% of a total vibrating energy and 46% of a peak vibrating energy.

According to the damping structure, the electronic device and the damping assembly disclosed in the above embodiment, the distance between the central part of the curved portion and the body portion of the chassis is longer than the distance between the two opposite ends of the curved portion and the body portion of the chassis. That is, the curved portion is single wave-shaped. The opposite end of the two compression springs of the two second damping assemblies are connected to the ends of the two second mass block and the two assembling portions of the first damping assembly, respectively. The natural frequency of the damping structures is adjustable. Therefore, the vibrations can be damped by the damping structures of the electronic device effectively under different operating conditions. When one of the natural frequencies of the damping structures matches the vibration frequency of the fans, a resonance will be generated, and the strong amplitude enhancement effect may be generated by the damping structures. The interaction between the vibrations generated by the fans during operation and the elastic member and the two compression springs of the damping structures can be conducted along the path in which the vibrations are transferred. Specifically, the vibrations generated by the fans during operation may be transferred to the damping structures. The wave-shaped curved portion of the elastic member and the two compression springs can absorb the vibrations effectively, and convert the vibrations into kinetic energy of the elastic member and the two compression springs. Accordingly, the vibrations generated by the fans during operation can be confined within the damping structures to dissipate energy. In addition, the damping structures can be facilitated to be assembled in the limited space between the hard disk drive and the fans and be prevented from interfering with other obstructions disposed in the aforementioned space. Thus, the damping structures can be adaptable to different specifications of the chassis. Accordingly, the assembly cost of the damping structures can be lowered while maintaining the damping effect of the damping structures.

In addition, each of damping assemblies may be independently disposed between a hard disk drive and fans as local resonators. In addition, the stiffness of the elastic members or compression springs and the mass of the mass blocks can be adjusted to correspondingly adjust the natural frequency of the damping assemblies. Therefore, the vibrations can be damped by the damping assemblies of the electronic device effectively under different operating conditions. Accordingly, the vibrations generated by the fans during operation can be confined within the damping assemblies to dissipate the total vibrating energy and the peak vibrating energy. Therefore, a flexible configuration of the damping structures of the first embodiment or the damping assemblies independently disposed in the chassis of the second embodiment and the third embodiment can be performed according to a damping requirement under different operating conditions and different vibration frequencies. Moreover, the electronic device includes multiple first magnetic members and the multiple second magnetic members. The first magnetic members attract the two assembling portions of the first damping assembly to install the elastic member onto the chassis. The two compression springs of the two second damping assemblies are fixed to the elastic member via the two second magnetic members attracting the elastic member. Therefore, the damping structures can be easily assembled and disassembled according to a damping requirement via the first magnetic members and the two second magnetic members without fastening the elastic member to the chassis via additional fasteners and fastening the two compression springs to the two assembling portions via additional fasteners. Accordingly, the flexibility of assembling the damping structures can be further improved.

In this embodiment, the damping structures of the invention can be applied to a server. The server can apply artificial intelligence (AI) computing, edge computing, and can also be used as a 5G server, a cloud server or a Vehicle-to-everything server.

It will be apparent to those skilled in the art that various modifications and variations can be made to the invention. It is intended that the specification and examples be considered as exemplary embodiments only, with the scope of the invention being indicated by the following claims.

What is claimed is:

1. A damping structure, configured to be disposed in a chassis, and the damping structure comprising:
a first damping assembly, comprising an elastic member and a first mass block, wherein the elastic member comprises two assembling portions and a curved portion, the two assembling portions are configured to be assembled on the chassis, two opposite ends of the curved portion are connected to the two assembling portions, respectively, a distance between a central part of the curved portion and the chassis is longer than a distance between the two opposite ends of the curved portion and the chassis, and the first mass block is disposed on the central part of the curved portion; and
at least one second damping assembly, comprising a compression spring and a second mass block, wherein an end of the second mass block is connected to an end of the compression spring;
wherein another end of the compression spring of the at least one second damping assembly is disposed on one of the two assembling portions of the first damping assembly.

2. The damping structure according to claim 1, wherein the central part of the curved portion has an assembling hole, the first mass block has an assembling protrusion, and the assembling protrusion is assembled into the assembling hole.

3. The damping structure according to claim 2, wherein the curved portion further has two notches, the two notches are located on two opposite sides of the assembling hole, respectively.

4. The damping structure according to claim 1, further comprising at least one magnetic member, wherein the at least one magnetic member is connected to an end of the compression spring of the at least one second damping assembly away from the second mass block, and the damping structure is fixed to the chassis via the at least one magnetic member which is configured to attract the chassis.

5. The damping structure according to claim 1, wherein a ratio of a length of the elastic member, a width of the elastic member and a height of the elastic member is 11:1.5:1, and a thickness of the elastic member is larger than or equal to 0.3 millimeters.

6. The damping structure according to claim 1, wherein a length of each of the two assembling portions is 13 millimeters, the curved portion has a curved bottom surface and a curved top surface facing away from each other, the curved bottom surface is configured to face the chassis, a radius of curvature of the curved bottom surface is larger than or equal to 21 millimeters and less than or equal to 22 millimeters, and a radius of curvature of the curved top surface is larger than or equal to 20 millimeters and less than or equal to 21 millimeters.

7. An electronic device, comprising:
a chassis;
a hard disk drive, disposed in the chassis;
at least one fan, disposed in the chassis; and
at least one damping structure, located between the hard disk drive and the at least one fan, and the at least one damping structure comprising:
a first damping assembly, comprising an elastic member and a first mass block, wherein the elastic member comprises two assembling portions and a curved portion, the two assembling portions are configured to be assembled on the chassis, two opposite ends of the curved portion are connected to the two assembling portions, respectively, a distance between a central part of the curved portion and the chassis is longer than a distance between the two opposite ends of the curved portion and the chassis, and the first mass block is disposed on the central part of the curved portion; and
at least one second damping assembly, comprising a compression spring and a second mass block, wherein an end of the second mass block is connected to an end of the compression spring;
wherein another end of the compression spring of the at least one second damping assembly is disposed on one of the two assembling portions of the first damping assembly.

8. The electronic device according to claim 7, wherein the central part of the curved portion has an assembling hole, the first mass block has an assembling protrusion, and the assembling protrusion is assembled into the assembling hole.

9. The electronic device according to claim 7, wherein the chassis comprises a body portion and at least one first magnetic member, the at least one first magnetic member is disposed on the body portion, the elastic member is made of magnetic material, and the at least one first magnetic member attracts one of the two assembling portions of the elastic member to install the elastic member onto the chassis.

10. The electronic device according to claim 9, further comprising at least one second magnetic member, wherein the at least one second magnetic member is connected to an end of the compression spring away from the second mass block, and the damping structure is fixed to the chassis via the at least one second magnetic member attracting the at least one first magnetic member.

11. A damping assembly, configured to be disposed in a chassis, and the damping assembly comprising:
an elastic member, comprising two assembling portions and a curved portion, wherein the two assembling portions are configured to be assembled on the chassis, two opposite ends of the curved portion are connected to the two assembling portions, respectively, and a distance between a central part of the curved portion and the chassis is longer than a distance between the two opposite ends of the curved portion and the chassis; and
a mass block, disposed on the central part of the curved portion.

12. The damping assembly according to claim 11, wherein the central part of the curved portion has an assembling hole, the mass block has an assembling protrusion, and the assembling protrusion is assembled into the assembling hole.

13. The damping assembly according to claim 12, wherein the curved portion further has two notches, the two notches are located on two opposite sides of the assembling hole, respectively.

14. The damping assembly according to claim 11, wherein the curved portion has a curved bottom surface and a curved top surface facing away from each other, the curved bottom surface is configured to be face the chassis, a radius of curvature of the curved bottom surface is larger than or equal to 21 millimeters and less than or equal to 22 millimeters, and a radius of curvature of the curved top surface is larger than or equal to 20 millimeters and less than or equal to 21 millimeters.

15. A damping assembly, configured to be disposed in a chassis, and the damping assembly comprising:
a compression spring, wherein an end of the compression spring is configured to be disposed on the chassis; and
a mass block, wherein an end of the mass block is connected to another end of the compression spring.

16. The damping assembly according to claim 15, further comprising a magnetic member, wherein the magnetic member is connected to an end of the compression spring away from the mass block, and the damping assembly is configured to be fixed to the chassis via the magnetic member.

17. The damping assembly according to claim 16, wherein the magnetic member is a magnet, and the damping assembly is configured to be fixed to the chassis via the magnetic member attracting the chassis.

18. The damping assembly according to claim 15, wherein the compression spring is made of metal, acrylic, resin or plastic material.

19. The damping assembly according to claim 15, wherein the mass block is cylindrical.
